(19) United States
(12) Patent Application Publication
(10) Pub. No.: US 2013/0003321 A1
(43) Pub. Date: Jan. 3, 2013

(54) NOISE SUPPRESSION STRUCTURE

(75) Inventor: Eiji Hankui, Tokyo (JP)

(73) Assignee: NEC CORPORATION, Tokyo (JP)

(21) Appl. No.: 13/634,462

(22) PCT Filed: Mar. 8, 2011
(86) PCT No.: PCT/JP2011/055340

§ 371 Date: Sep. 12, 2012

(30) Foreign Application Priority Data
Mar. 15, 2010 (JP) 2010-058237

(51) Int. Cl. H05K 9/00

(52) U.S. Cl. 361/748

(57) ABSTRACT

Provided is a noise suppression structure having a current control unit that controls current, and which is provided on a ground layer. The current control unit comprises: a first metal surface provided on the ground layer with an interval therebetween, and having a first end part and a second end part on the opposite side to the first end part; a second metal surface provided on the first metal surface with an interval therebetween, and having a first end part and a second end part on the opposite side to the first end part; a first short-circuit board disposed on the first end part of the first metal surface, and which connects the first metal surface and the ground layer; and a second short circuit board disposed on the second end part of the second metal surface, and which connects the second metal surface and the first metal surface. A first open end is formed on the second end part of the first metal surface. A second open end is formed on the first end part of the second metal surface.

### TECHNICAL FIELD

The present invention relates to a noise suppression structure that can be applied to electronic and electrical equipment including wireless application devices such as mobile phones, wireless personal computers, and personal digital assistants.

### BACKGROUND ART

Wireless devices such as mobile phones and wireless personal computers have become widely used owing to their convenience. Reductions in the thinness and size of wireless devices have advanced recently. Moreover, the mounting of wireless systems on wireless application devices is also proceeding.

FIG. 14 to FIG. 16 show the basic configuration of an ordinary mobile terminal in a conventional wireless application device 30.

FIG. 14 is a perspective view that shows the entire mobile terminal. FIG. 15 is a perspective view that shows only a noise suppression structure 40. FIG. 16 is a side view of the noise suppression structure 40 shown in FIG. 15.

In this wireless application device 30, at least an antenna unit 21, a wireless circuit unit 22, and a digital circuit unit 23 are mounted on a printed substrate 24. The antenna unit 21 sends and receives radio waves for performing communication with a base station or the like. The wireless circuit unit 22 processes signals that are transmitted from the antenna unit 21 or signals that are received by the antenna unit 21. The digital circuit unit 23 processes digital signals for data processing.

A ground layer 43 is disposed at an inner layer of the printed substrate 24. The ground layer 43 is a common ground of the digital circuit unit 23 and the wireless circuit unit 22.

A signal layer and a power supply layer are formed at the inner layer of the printed substrate 24, but they are not illustrated in the figure here. Patterns for transmitting signals corresponding to respective purposes such as digital signals and analog signals are formed at the signal layer and power supply layer.

The noise suppression structure 40 described later is mounted on the printed substrate. The noise suppression structure 40 suppresses electromagnetic interference that occurs between the digital circuit unit 23 and the wireless circuit unit 22.

As understood by referring to FIG. 14, in the wireless application device 30, the wireless circuit unit 22 and the digital circuit unit 23 coexist on the same substrate. In actuality, the wireless circuit unit 22 and the digital circuit unit 23 are densely mounted in the wireless application device 30. For this reason, in this kind of printed circuit board 24, due to the electromagnetic noise that is generated from the digital circuit unit 23 mixing into the antenna unit 21 and the wireless circuit unit 22, electromagnetic interference is generated, thereby affecting the receiving characteristic of the antenna unit.

The digital circuit unit 23 handles a clock signal with a fundamental around several 10 MHz to several 100 MHz and data bus signals. Among the noise in the high-frequency band of these signals, when the noise that matches the antenna reception band (800 MHz band and 2 GHz band and the like) mixes in with the wireless circuit unit 22 or the antenna unit 21, the wireless characteristics such as the antenna receiving sensitivity fall. Also, when current from the antenna unit 21 mixes into the digital circuit unit 23, blending (mixing) of the transmission wave and digital signal occurs, which can become noise.

In this kind of wireless application device 30, current that is generated from the digital circuit unit 23 and the wireless circuit unit 22 or the antenna unit 21 can behave as noise. This current mixes in from one circuit unit to another circuit unit via the ground layer 43 that is common. That is to say, mixing in of noise current from the digital circuit unit 23 to the wireless circuit unit 22 (or the antenna unit 21), and mixing in of current from the wireless circuit unit 22 (or the antenna unit 21) to the digital circuit unit 23 occur.

The electromagnetic interference due to the mixing in of noise that occurs between the digital circuit unit 23 and the wireless circuit unit 22 as mentioned above tends to become more pronounced with reductions in the size and thinness, and as more wireless systems are mounted. In order to ensure a better communication quality, it has been desired to further suppress the electromagnetic noise between the digital circuit unit 23 and the wireless circuit unit 22. Also, since the frequency bands tend to expand in a wireless application device as more wireless systems are mounted, a wider bandwidth (including multi-bandwidth) of the frequency that suppresses electromagnetic interference has been desired.

In order to suppress electromagnetic interference, for example, Patent Document 1 provides a structure of noise suppression focused on the current that flows on the surface of metal.

In the mobile wireless application device disclosed in Patent Document 1, in order to separate a wireless circuit unit and a digital circuit unit, a current control mechanism that suppresses electromagnetic coupling is mounted between the both circuit units within a printed circuit board. This current control mechanism provides metal planes at the upper surface and lower surface in parallel so as to sandwich the ground layer. A via hole array is formed in a linear shape at the positions of both sides of the metal planes and at positions separated by desired intervals from the end portions of the metal planes in a direction that couples the wireless circuit unit and the digital circuit unit.

In Patent Document 1, the noise suppression structure is disposed with respect to the upper and lower layer of a metal plane (ground). Here, since the structure and principle of the noise suppression structure of the upper layer and lower layer are the same, only the case of disposing the same noise suppression structure on the upper layer shall be described.

The noise suppression structure 40 shown in Patent Document 1, as understood by referring to FIG. 16, has a metal plane 41 that is formed parallel to a ground layer 43, and a short-circuiting plane 42 that is erected in the middle portion of the metal plane 41, in order to suppress current that flows through the ground of the substrate. The length of the metal plane 41 when viewed horizontally from the short-circuiting plane 42 is the same. It is constituted as a resonator that sets the length of the metal plane 41 to λ/4, which is ¼ of the wavelength λ, of the desired frequency f, as shown in FIG. 15. For this reason, the open portion at the left end and the right end behaves as an open end electrically, and the input impedance is a high value. When the impedance is high, the current In that flows through the ground is hindered from flowing. As a result, the mixing in of electromagnetic noise from one side to the other side, that is to say, “digital circuit unit 23 side Ds→wireless circuit unit 22 side Ws” and “wireless circuit unit 22 side Ws→digital circuit unit 23 side Ds” is suppressed.

Also, Patent Document 2 proposes a noise suppression structure. In this noise suppression structure, a first conductor through which high-frequency current flows and a noise suppression layer are electromagnetically coupled via an insulating layer. In this noise suppression structure, additionally the noise suppression layer is electromagnetically coupled to a second conductor via an insulating layer.

### PRIOR ART DOCUMENTS

### Patent Documents

[Patent Document 1] Japanese Unexamined Patent Application, First Publication No. 2002-314491
[Patent Document 2] Japanese Unexamined Patent Application, First Publication No. 2007-243007

### SUMMARY OF THE INVENTION

### Problem to be Solved by the Invention

In the noise suppression structure 40 shown in Patent Document 1, in order to orient open portions having a high impedance toward both circuit units, two metal planes 41 having a length of λ/4 are arranged side-by-side with the short circuiting plane 42 serving as a boundary.

In this kind of conventional constitution, two resonators having a length of λ/4 are arranged on the same plane. For that reason, there was a tendency to take up the mounting surface area. In relation to noise suppression in a high frequency band, since the wavelength is shorter, the mounting surface area becomes small which is preferred. However, in the case of a low frequency being targeted, since the wavelength becomes longer, there has been the problem of the mounting surface area becoming larger.

The noise suppression structure shown in Patent Document 2 is a lamellar body in which a single noise suppression layer is electromagnetically coupled between the first and second conductors via an insulating layer. For this reason, there is the problem of a definite area being required for the noise suppression layer in order to obtain the predetermined noise suppression effect.

As stated above, in a wireless application device with reduced size and thinness, in particular a noise suppression structure with a small mounting area has been desired. However, in a conventional constitution since a resonator is constituted on the same surface, particularly in the case of targeting a low frequency or the like, there has been a tendency for the mounting area to increase.

The present invention has been achieved in view of the above circumstances. An exemplary object of the present invention is to provide a compact noise suppression structure that reduces the effect of electromagnetic interference that occurs between the digital circuit unit and the wireless circuit unit.

### Means for Solving the Problem

In order to solve the aforementioned problems, a noise suppression structure of the present invention includes a current control unit provided on a ground layer and controlling current. The current control unit includes: a first metal plane that is provided above the ground layer with an interval therebetween, and having a first end portion and a second end portion on an opposite side of the first end portion; a second metal plane that is provided above the first metal plane with an interval therebetween, and having a first end portion and a second end portion on an opposite side of the first end portion; a first short circuit plate that is arranged at the first end portion of the first metal plane, and connects the first metal plane and the ground layer; and a second short circuit plate that is arranged at the second end portion of the second metal plane, and connects the second metal plane and the first metal plane. A first open end is formed at the second end portion of the first metal plane. The second open end is formed at the first end portion of the second metal plane.

### Effect of the Invention

By arranging the current control unit of the present invention between a digital circuit unit and a wireless circuit that are mounted on a printed substrate, it is possible to obtain a noise suppression structure in which the value of the impedance is increased at a region with a reduced mounting area. Thereby, it is possible to suppress the mixing in to another circuit unit side of current that is generated from one circuit and transmitted through the ground plane, and reduce electromagnetic interference that is produced between both the digital circuit unit and the wireless circuit.

Also, in the noise suppression structure of the present invention, the first metal plane is provided above the ground layer with an interval therebetween, and the second metal plane is provided above the first metal plane with an interval therebetween. With this constitution, less mounting area is required.

According to an exemplary embodiment of the present invention, a notch portion is provided in a portion of the metal plane. With this constitution, it is possible to broaden the frequency that suppresses current. Moreover, according to an exemplary embodiment of the present invention, the open ends that are formed at the end portions of the metal planes are oriented toward the side at which the digital circuit unit is mounted and the side at which the wireless circuit unit and the antenna unit are mounted. With this constitution, it is possible to suppress both the mixing in of noise from the digital circuit unit side to the wireless circuit unit side, and the mixing in of current from the wireless circuit unit side to the digital circuit unit side, and it is possible to effectively perform noise suppression in a wireless application device.

### BRIEF DESCRIPTION OF THE DRAWINGS

FIG. 1 is a perspective view that shows a noise suppression structure according to a first exemplary embodiment of the present invention.

FIG. 2 is an exploded perspective view of the noise suppression structure shown in FIG. 1.

FIG. 3 is a transverse sectional view taken along line III-III of FIG. 1.

FIG. 4 is a plan view of a metal plane of the noise suppression structure of FIG. 1.

FIG. 5 is a side view that shows the positional relationship of the noise suppression structure shown in FIG. 1 with respect to a digital circuit unit and a wireless circuit.

FIG. 6 is a perspective view that shows a noise suppression structure according to a second exemplary embodiment of the present invention.

FIG. 7 is an exploded perspective view of the noise suppression structure shown in FIG. 6.

FIG. 8 is a transverse sectional view taken along line VIII-VIII of FIG. 6.

FIG. 9 is a plan view that shows a metal plane of the noise suppression structure of FIG. 6.

FIG. 10 is a plan view that shows a metal plane of the noise suppression structure of FIG. 6.

FIG. 11 is a perspective view that shows a noise suppression structure according to a third exemplary embodiment of the present invention.

FIG. 12 is an exploded perspective view of the noise suppression structure shown in FIG. 11.

FIG. 13 is a transverse sectional view taken along line XIII-XIII of FIG. 11.

FIG. 14 is a perspective view that shows a basic configuration when a conventional noise suppression structure is mounted in a wireless application device.

FIG. 15 is a perspective view that shows only the noise suppression structure in the structure of FIG. 14.

FIG. 16 is a side view of the noise suppression structure shown in FIG. 15.

### EMBODIMENTS FOR CARRYING OUT THE INVENTION

### First Exemplary Embodiment

A noise suppression structure of a first exemplary embodiment of the present invention shall be described with reference to FIG. 1 to FIG. 5.

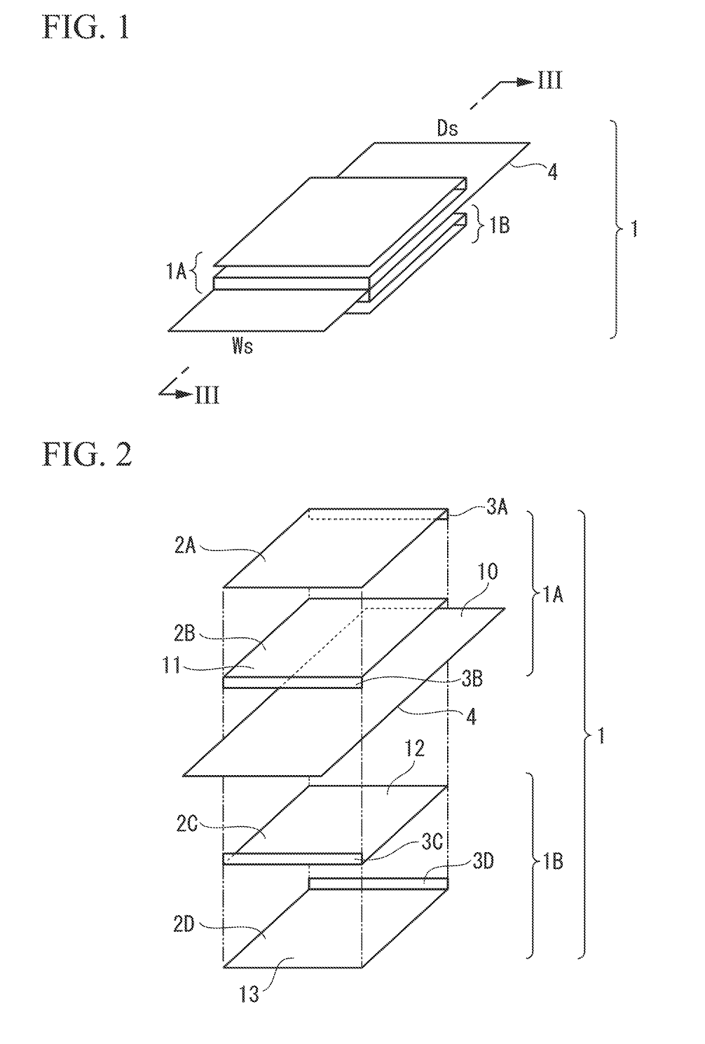

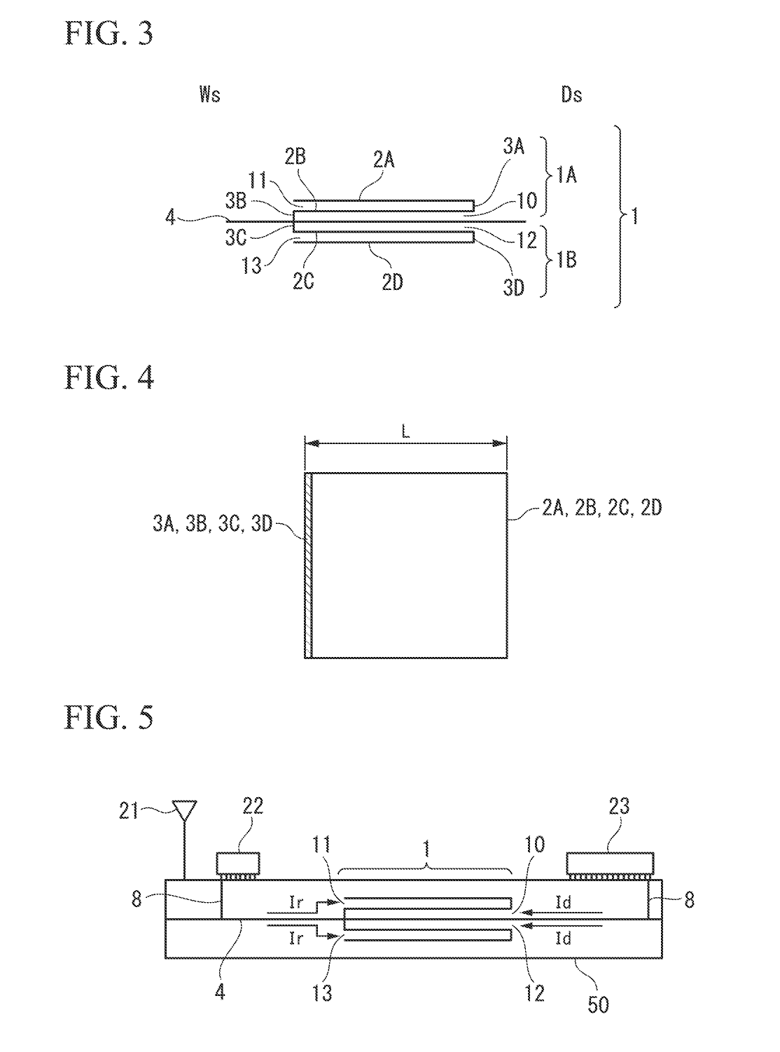

FIG. 1 to FIG. 5 show a noise suppression structure 1 according to the first exemplary embodiment of the present invention. FIG. 1 is a perspective view that shows the noise suppression structure 1 according to the first exemplary embodiment of the present invention. FIG. 2 is an exploded perspective view that shows the noise suppression structure 1 of FIG. 1. FIG. 3 is a side view that shows the noise suppression structure 1 of FIG. 1. FIG. 4 is a plan view that shows a metal plane of the noise suppression structure 1. FIG. 5 shows an example of providing the noise suppression structure 1 that suppresses noise in a substrate that constitutes a wireless application device.

This noise suppression structure 1, as shown in FIG. 5, is arranged between a digital circuit unit 23 and a wireless circuit unit 22. The noise suppression structure 1 that is arranged in this manner blocks electromagnetic coupling between the digital circuit unit 23 and the wireless circuit unit 22, and prevents the mixing in of noise current that mutually flows in between the digital circuit unit 23 and the wireless circuit unit 22.

In this noise suppression structure 1, a reduction of area of the mounting area is achieved by doubly piling up in a layered manner the constitution that suppresses current. Moreover, orienting the open ends that serve as open portions toward the digital circuit unit 23 side Ds and the wireless circuit unit 22 side Ws suppresses the mixing in of current that occurs at both the digital circuit unit 23 and the wireless circuit unit 22.

Specifically, as is understood by referring to FIG. 1 to FIG. 3, the noise suppression structure 1 is constituted by a first current suppression unit 1A that is arranged on the upper layer side and a second current suppression portion 1B that is arranged on the lower layer side, so as to sandwich the ground layer 4. This constitution effectively controls current that flows through the ground layer 4 of a substrate. The constitutions and dimensions of the current control units 1A and 1B are exactly the same. The current control units 1A and 1B are arranged in a vertically symmetrical manner with respect to the ground layer 4.

The noise suppression structure 1 that is shown here is provided in a multi-layer printed substrate 50 that includes a plurality of layers (refer to FIG. 5). The digital circuit unit 23 is provided at one side of the noise suppression structure 1, and the wireless circuit unit 22 is provided at the other side.

A dielectric material such as glass epoxy is filled in between each layer (the metal planes (metal plates) 2A to 2D, ground layer 4) of the multi-layer printed substrate 50, but is omitted in the figures. The via holes used here have a constitution in which a conductive layer is formed on the periphery of an air hole. The via hole that penetrates the metal pattern is conductive with the metal pattern.

The first current control unit 1A and the second current control unit 1B that constitute the noise suppression structure 1 shall be described. The first current control unit 1A is constituted by two metal planes 2A and 2B, and two short circuit plates 3A and 3B. From the upper layer, they are arranged in the order of the first metal plane 2A, the first short circuit plate 3A, the second metal plane 2B, and the second short circuit plate 3B.

The short-circuit plates 3A and 3B are in actuality constituted by a plurality of via holes that are aligned in a row within that region. In the present constitution, since the interval between adjacent via holes is a sufficiently small narrow pitch with respect to the wavelength, they may be regarded as a short-circuit state electrically. Here, this kind of row of a plurality of via holes aligned with a narrow pitch is called a “short circuit plate”.

The metal planes 2A and 2B that constitute the first current control unit 1A are formed by metal patterns. The size in the width direction of the metal planes 2A and 2B are the same as the size in the width direction of the substrate. The metal planes 2A and 2B overlap with a predetermined distance in the vertical direction. The metal plane 2B is arranged closer to the ground layer 4 than the metal plane 2A. The short circuit plate 3B is provided at one end portion (first end portion) of the metal plane 2B. The short circuit plate 3B is connected to the metal plane 2B and the ground layer 4. A pair of transmission lines (first transmission line) is constituted by the metal plane 2B and the ground layer 4. An open end (open end) 10 is formed at the other end portion (second end portion) of the metal plane 2B. This open end 10 is constituted by an opening between the metal plane 2B and the ground layer 4. A short circuit end (short circuit plane) is formed at the one end portion of the metal plane 2B. This short circuit end is constituted by the short circuit plate 3B. With this constitution, the open end 10 faces the digital circuit unit 23 side Ds, and the short circuit plane 3B faces the wireless circuit unit 22 side Ws.

The short circuit plate 3A is positioned on the opposite side of the short circuit plate 3B with respect to the metal planes 2A and 2B, and is provided at the other end portion (second end portion) of the metal plane 2A. This short circuit plate 3A is connected to the metal plane 2A and metal plane 2B. A pair of transmission lines (second transmission line) is constituted by the metal plane 2A and the metal plane 2B. A short circuit end (short circuit plane) is formed at the other end portion (second end portion) of the metal plane 2A. This short circuit end is constituted by the short circuit plate 3A. An open end 11 is formed at the one end portion (first end portion) of the metal plane 2A. This open end 11 is constituted by the opening between the metal plate 2A and the metal plate 2B. With this constitution, the open end 11 faces the wireless circuit unit 22 side Ws, and the short circuit plane faces the digital circuit unit 23 side Ds.

Basically, the second current control unit 1B has the same constitution as the first current control unit 1A. The second current control unit 1B is arranged on the lower layer side of the ground layer 4 in order to effectively control the current which flows through the ground layer 4 of the substrate. The second current control unit 1B is arranged vertically symmetrical to the first current control unit 1A, with the ground layer 4 being common to both.

The second current control unit 1B is constituted by two metal planes 2C and 2D and two short circuit plates 3C and 3D similarly to the first current control unit 1A. The metal planes 2C and 2D are formed by metal patterns. The short circuit plates 3C and 3D are in actuality constituted by a plurality of via holes aligned in a row within that region, similarly to the aforementioned short circuit plates 3A and 3B. The shape and dimensions of the constituent elements of the second current control unit 1B are the same as the constituent elements of the first control portion 1A. The arrangement positions at the ground layer 4 of the constituent elements of the second current control unit 1B also agree with the constituent elements of the first current control unit 1A.

For this reason, in the second current control unit 1B, the ground layer 4 and the metal plane 2C form a transmission line (first transmission line) having the short circuit plate 3C as a short circuit plane. An open end 12 of this line faces the digital circuit unit 23 side Ds in the same manner as the first current control unit. Also, the metal plane 2C and the metal plane 2D form a transmission line (second transmission line) that has the short circuit plate 3D as a short circuit plane. An open end 13 of this line also faces the side of the wireless circuit unit 22 in the same manner as the open end 11 of the first current control unit 1A.

That is to say, in the present exemplary embodiment, at both the upper side layer and lower side layer so as to sandwich the ground layer 4, the transmission lines facing the open ends 10 and 12 at the digital circuit unit 23 side Ds (upper side: metal plane 2B-short circuit plate 3B-ground layer 4, lower side: metal plane 2C-short circuit plate 3C-ground layer 4), and the transmission lines facing the open ends 11 and 13 at the wireless circuit unit 22 side Ws (upper side: metal plane 2A-short circuit plate 3A-metal plane 2B, lower side: metal plane 2D-short circuit plate 3D-metal plane 2C) are formed in the layer direction.

In an actual wireless application device, the noise suppression structure 1 that sandwiches the ground layer 4 and the wireless circuit unit 22 and the digital circuit unit 23 that are positioned at both ends thereof, are contained in a housing, but the illustration of the housing is omitted here. In the same manner, a liquid crystal display, operation buttons, an operation keyboard and the like are mounted on the device, but their illustration is omitted.

Next, the operation and principle of the noise suppression structure 1 that is constituted in the aforementioned manner shall be described.

FIG. 4 shows a plan view of the metal planes 2A, 2B, 2C, and 2D of the noise suppression structure 1. As is apparent from FIG. 4, the metal planes 2A, 2B, 2C, and 2D have the same dimensions. The length (L) with respect to the lengthwise direction of the outer shape of the metal planes 2A, 2B, 2C, and 2D is set to a length that, with respect to the desired frequency f (wavelength λ), resonates at a ¼ wavelength (L=λ/4).

Generally, in a transmission line having one end serve as a electrical short circuit end, a position that is located ¼ of the wavelength away behaves as an open end, and the input impedance at that position is an extremely high value (ideally infinitely large).

In the noise suppression structure 1 of the present exemplary embodiment, the metal plate 2B and the ground layer 4 in the first current control unit 1A form a transmission line that short circuits the terminal side just by the short circuit plate 3B. Moreover, the length of the metal plane 2B that corresponds to the transmission line is set to a length that corresponds to ¼ of the wavelength. For this reason, at the open end 10 that faces the digital circuit unit 23 side Ds, the impedance has an extremely high value. Also, at the second current control unit 1B, similarly the metal plane 2C and the ground layer 4 form a transmission line having a length of ¼ of the wavelength with the terminal being the open end 12. For this reason, the impedance at the open ends 10 and 12 is extremely high. In the present constitution, the open ends 10 and 12 with this kind of high impedance are oriented toward the digital circuit unit 23 side Ds at both the layers above and below the ground layer 4.

The open ends 11 and 13 with high impedance are oriented toward the wireless circuit unit 22 side Ws. The transmission line that constitutes the open end 11 is formed by the metal plane 2A, the metal plane 2B and the short circuit plate 3A in the first current control unit 1A. Also, the transmission line that constitutes the open end 13 is formed by the metal plane 2C, the metal plane 2D and the short circuit plate 3D in the second current control unit 1B.

FIG. 5 explains the action of the open ends 10 to 13 with respect to both currents when constituting the noise suppression structure 1 according to the present exemplary embodiment within the substrate of the wireless application device. The ground layer 4 of the digital circuit unit 23 and the wireless circuit unit 22 is made common via a signal pattern 8.

As is understood by referring to FIG. 5, the open ends 10 and 12 that are oriented toward the digital circuit unit 23 side Ds have a high impedance with respect to the noise current Id that mixes in via the ground layer 4 from the digital circuit unit 23 side Ds to the wireless circuit unit 22 side Ws. Due to this effect, the noise current Id is hindered from flowing. As a result, mixing of the noise current Id that is generated from the digital circuit unit 23 into the wireless circuit unit 22 or the antenna unit 21 is suppressed.

On the other hand, the open ends 11 and 13 that are oriented toward the wireless circuit unit 22 side Ws have a high impedance with respect to the current Ir. Due to this effect, the current Ir is hindered from flowing, and so mixing of the current Ir from the wireless circuit unit 22 side Ws to the digital circuit unit 23 side Ds is suppressed.

The current control units 1A and 1B of the noise suppression structure 1 according to the present exemplary embodiment as described above are constituted by orienting the open ends 10 to 13 with high impedance toward both the digital circuit unit 23 side Ds and the wireless circuit unit 22 (or antenna unit 21) side Ws (As). For that reason, it is possible to effectively suppress noise that mixes in from both the circuits 22 and 23. Therefore, the noise suppression structure 1 according to the present exemplary embodiment exhibits an effect with respect to suppression of the mixing in of noise from the digital circuit unit 23 to the wireless circuit unit 22, and the mixing in of noise from the wireless circuit unit 22 to the digital circuit unit 23. Also, the current control units 1A and 1B are formed in the layer direction of the substrate. For this reason, in the noise suppression structure 1 according to the present exemplary embodiment, it is possible to reduce the mounting area compared with a conventional constitution.

That is to say, the current control units 1A and 1B are arranged between the digital circuit unit 23 and the wireless circuit unit 22 that are mounted on the printed substrate 50. With this constitution, it is possible to obtain a noise suppression structure with a greater impedance value at the open ends 10 to 13. Thereby, it suppresses the mixing in of current that is generated from one circuit and transmitted through the ground plane to the other circuit. As a result, it is possible to reduce electromagnetic interference that is produced between both the digital circuit unit 23 and the wireless circuit unit 22.

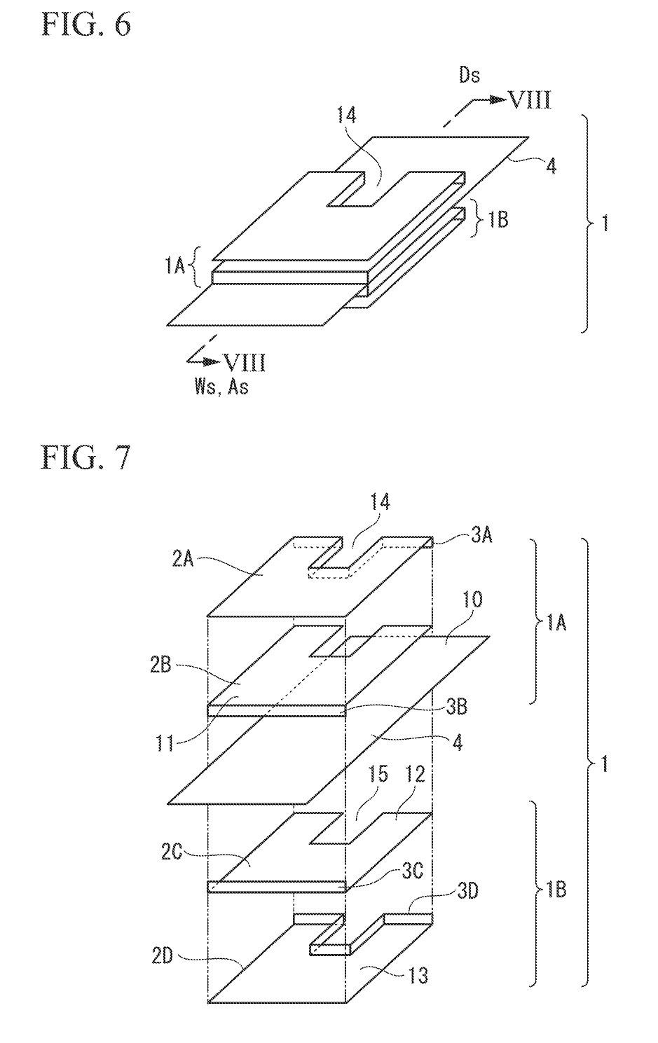

A second exemplary embodiment of the present invention shall be described referring to FIG. 6 to FIG. 10.

The preceding first exemplary embodiment showed a constitution that suppresses current flowing in from both the circuits of the digital circuit unit 23 and the wireless circuit unit 22. In addition to this, with the constitution shown in the second exemplary embodiment, a wider bandwidth of the noise suppression frequency may be sought.

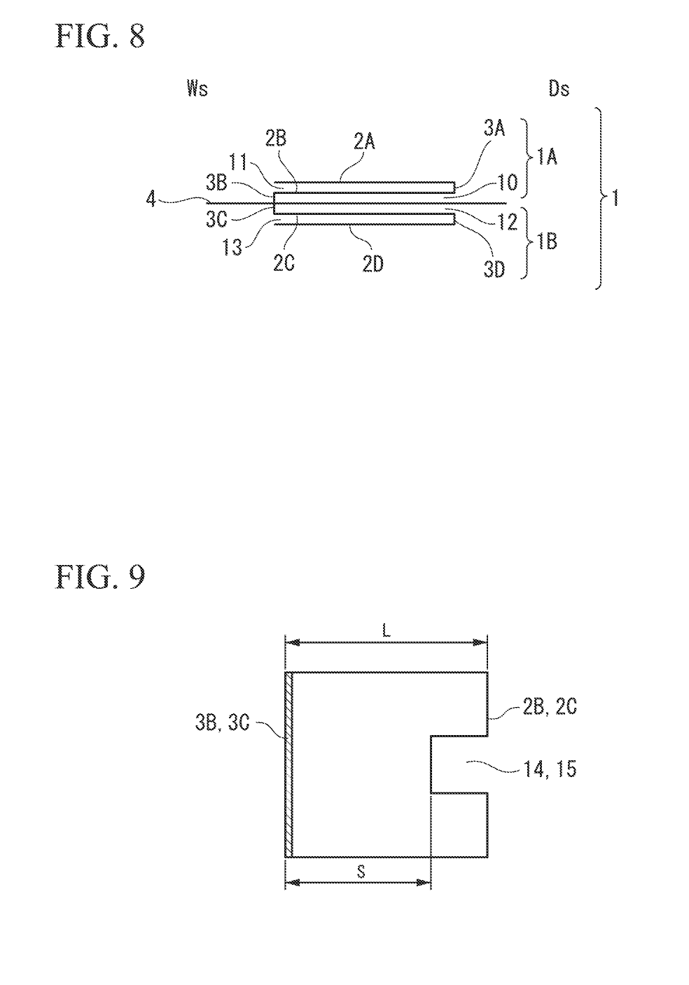

FIG. 6 to FIG. 8 show the noise suppression structure 1 according to the second exemplary embodiment of the present invention. FIG. 6 is a perspective view that shows the noise suppression structure 1. FIG. 7 is an exploded perspective view that shows the noise suppression structure 1 of FIG. 6. FIG. 8 is a side view that shows the noise suppression structure 1 of FIG. 6.

In the second exemplary embodiment, the noise suppression structure 1 is arranged between the digital circuit unit 23 and the wireless circuit unit 22, in the same manner as the first exemplary embodiment. The noise suppression structure 1 that is arranged in this manner blocks electromagnetic coupling between the wireless circuit unit 22 and the digital circuit unit 23, and prevents the mixing in of current that mutually flows in between the digital circuit unit 23 and the wireless circuit unit 22.

Specifically, the noise suppression structure 1 of the second exemplary embodiment, in the same manner as the first exemplary embodiment, is constituted by a first current suppression unit 1A that is arranged on the upper layer side and a second current suppression portion 1B that is arranged on the lower layer side, so as to sandwich the ground layer 4. This constitution effectively controls current that flows through the ground layer 4 of a substrate. The constitutions and dimensions of the current control units 1A and 1B are exactly the same. The current control units 1A and 1B are arranged in a vertically symmetrical manner with respect to the ground layer 4.

The first current control unit 1A is constituted by two metal planes 2A and 2B, and two short circuit plates 3A and 3B, in the same manner as the first exemplary embodiment. From the upper layer, they are arranged in the order of the first metal plane 2A, the first short circuit plate 3A, the second metal plane 2B, and the second short circuit plate 3B. The size in the width direction of the metal planes 2A and 2B that constitute the first current control unit 1A are the same as the size in the width direction of the substrate 50. The metal planes 2A and 2B overlap with a predetermined distance in the vertical direction (layer direction). The second exemplary embodiment and first exemplary embodiment differ on the point of providing a notch portion 14 with a rectangular shape in a portion of the side facing the digital circuit unit 23. Due to these notch portions 14, a change occurs in the length of the metal planes 2A and 2B between the digital circuit unit 23 and the wireless circuit unit 22. As will be described below, this is in order to broaden the noise suppression frequency.

The notch portion 14 is provided near the center of each metal plane 2A and 2B. The length at the region in the middle portion of the metal planes 2A and 2B is set to be short. The length of the outer sides of the metal planes 2A and 2B, that is to say, the length of the regions positioned on both sides of the substrate 50, is set to be long. The notch portion 14 is provided at the other end portion (second end portion) of the metal planes 2A and 2B.

The metal plane 2B is arranged closer to the ground layer 4 than the metal plane 2A. The short circuit plate 3B is provided at one end portion (first end portion) of the metal plane 2B. That is to say, the short circuit plate 3B is provided on the opposite side of the other side which has the notch portion 14. The short circuit plate 3B is connected to the metal plane 2B and the ground layer 4. For this reason, a pair of transmission lines is constituted by the metal plane 2B and the ground layer 4. An open end 10 is formed at the other end portion of the metal plane 2B. This open end 10 is constituted by an opening between the metal plane 2B and the ground layer 4. A short circuit end (short circuit plane) is formed at the one end portion of the metal plane 2B. This short circuit end is constituted by the short circuit plate 3B. In this case too, similarly to the first exemplary embodiment, the open end 10 faces the digital circuit unit 23 side Ds.

The short circuit plate 3A is disposed along the end portion of the metal plane 2A of the notch portion 14 side (that is to say, the second end portion of the metal plane 2A). This short circuit plate 3A is connected to the metal planes 2A and 2B. A pair of transmission lines is constituted by the metal plane 2A and the metal plane 2B. The open end 11 faces the wireless circuit unit 22 side Ws.

The second current control unit 1B has the same constitution as the first current control unit 1A. The second current control unit 1B is arranged vertically symmetrical to the first current control unit 1A with respect to the substrate 50 (the ground layer 4). A notch portion 15 is provided in the metal planes 2C and 2D on the side facing the digital circuit unit 23. The ground layer 4 and the metal plane 2C form a transmission line (first transmission line) having the short circuit plate 3C as a short circuit plane. The open end 12 of this line faces the digital circuit unit 23 side Ds. The metal plane 2C and the metal plane 2D form a transmission line (second transmission line) that has the short circuit plate 3D as a short circuit plane. The open end 13 of this line faces the wireless circuit unit 22 side Ws.

Next, the operation and principle of the noise suppression structure 1 of the second exemplary embodiment that is constituted in the aforementioned manner shall be described.

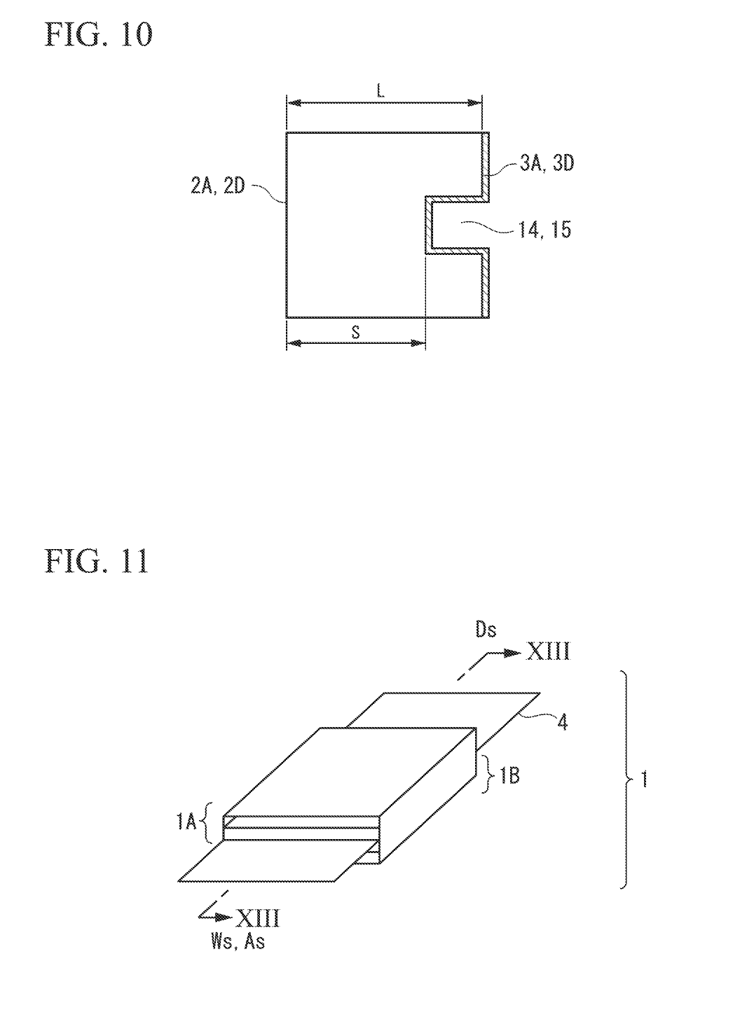

FIG. 9 is a plan view of the metal planes 2B and 2C. FIG. 10 is a plan view of the metal planes 2A and 2D. The shapes and dimensions of the metal planes 2A to 2D are the same. However, the shapes of the end portions that connect the short circuit plates 3A to 3D differ among the metal planes 2A to 2D. The length of the metal planes 2A to 2D (in this case, the length in the length direction of the substrate 50) is denoted as “L”. The length of the portion that excludes the notch portions 14 and 15 near the center portion of the metal planes 2A to 2D is denoted as “S”. In the case of the present constitution, there is the relationship of “L>S”. Moreover, “L” and “S” are set to the resonant length of ¼ of the wavelength, with respect to the respective desired differing frequencies f₁ and f₂. That is to say, they are set to L=λ₁/4, and S=λ₂/4 (wavelengths λ₁ and λ₂ being the wavelengths of the frequencies f₁ and f₂, respectively).

In the second exemplary embodiment, as described in the first exemplary embodiment, they form a transmission line that short circuits the terminal side. Moreover, the length of the metal plane that corresponds to the transmission line is set to a length that corresponds to ¼ of the wavelength. For this reason, the impedance at the open ends 10 to 13 facing both circuit unit sides has an extremely high value.

Moreover, due to the notch portions 14 and 15 being formed in the second exemplary embodiment, transmission lines that resonate at two frequencies are formed in the single metal planes 2A to 2D. That is to say, the notch portions 14 and 15 are provided near the center portion of the metal planes 2A to 2D. With this constitution, a transmission line that corresponds to the length L of the original metal planes 2A to 2D is formed on the outer sides (both sides of the substrate 50), and a transmission line that corresponds to the length S that is shorter by the amount of the notch portions 14 and 15 is formed near the center portion.

Specifically, the metal planes 2A to 2D at the outer sides that correspond to the transmission line having the length L (=λ₁/4) resonate at the frequency f₁. On the other hand, the metal planes 2A to 2D at the center portions that correspond to the transmission line having the length S (=λ₂/4) resonate at the frequency f₂. For this reason, by obtaining the wideband suppression effect of two frequency components with respect to current that flows through the ground plane of the substrate 50, it is possible to achieve a wider bandwidth of the noise suppression frequency.

As is shown in FIG. 9 and FIG. 10, the metal planes 2A and 2D and the metal planes 2B and 2C used in the second exemplary embodiment all have the same size and dimensions, and are also similar on the point of having the notch portions 14 and 15 provided in a portion thereof. However, the metal planes 2A and 2D and the metal planes 2B and 2C differ on the following point. In the metal planes 2B and 2C, the short circuit plates 3B and 3C are arranged on the opposite side of the notch portions 14 and 15. In the metal planes 2A and 2D, the short circuit plates 3A and 3D are arranged along the rectangular notch portions 14 and 15. In this kind of constitution, as is clear by referring to FIG. 9 and FIG. 10, there exists a region on the outer sides in which the transmission line that corresponds to the resonance frequency f₁ has the length L (=λ₁/4), and a region in the center portion in which the transmission line that corresponds to f₂ has the length S (=λ₂/4).

For this reason, in the metal planes 2A and 2D and the metal planes 2B and 2C, the positions of the short circuit plates differ, but since the transmission lines are set to lengths of ¼ of the wavelength, a high impedance is obtained in the two frequency bands at the open end sides. As a result, a wider band suppression effect can be obtained with respect to the noise current that is mixed in from the open end sides.

The reason for forming the transmission line with length L that is longer than length S on the outer sides in the second exemplary embodiment shall be explained below.

Generally, most of the frequencies that are used in an a wireless application device are in a several MHz to several GHz band, with high frequency bands such as the 800 MHz band and the 2 GHz band being utilized by mobile phones and the like. In these frequency bands, a standing wave is generated on the ground plane of the substrate 50, and current tends to flow through the edge portions of both sides. Also, in the case of considering the attenuation of the harmonic component of noise, the noise level tends to become higher more at the low-frequency side like 800 MHz than the high-frequency side like 2 GHz. For this reason, in the present constitution, the metal plane with the length L corresponding to the low-frequency transmission path is arranged on the outer sides, with the object of effectively performing suppression of current on the low-frequency side that flows easily at the edge portions of the substrate 50 and moreover whose level tends to become high.

In the noise suppression structure 1 of the second exemplary embodiment as described above, providing the notch portions 14 and 15 in the metal planes 2A to 2D forms transmission lines corresponding to two frequencies on the single metal planes 2B and 2C. Moreover, the transmission line on the low-frequency side in which the noise level tends to become high is arranged on the outer sides (both sides of the substrate 50). For this reason, an effect is obtained with respect to noise current that is generated from the digital circuit unit 23, is transmitted along the substrate 50, and mixes into the wireless circuit unit 22, and current from the wireless circuit unit 22 side that is transmitted along the substrate 50 and mixes into the digital circuit unit 23. In addition, since a noise suppression effect is obtained in two frequency bands, there is the advantage of a widening of the noise suppression frequency.

That is to say, in the noise suppression structure 1 of the second exemplary embodiment, metal planes of a dual structure are stacked up along the height direction of the substrate. With this structure, less mounting area is required. Moreover, by providing the partial notch portions 14 and 15, it is possible to broaden the frequency that suppresses current. Moreover, the open ends 10 to 13 that are formed at the end portions of the metal planes 2A to 2D are oriented to both the side at which the digital circuit unit 23 is mounted and the side at which the wireless circuit unit 22 and the antenna unit 21 are mounted. With this constitution, it is possible to suppress both the mixing in of noise from the digital circuit unit 23 side Ds to the wireless circuit unit 22 side Ws, and the mixing in of current from the wireless circuit unit 22 side Ws to the digital circuit unit 23 side Ds. As a result, noise suppression in a wireless application device becomes possible.

A third exemplary embodiment of the present invention shall be described referring to FIG. 11 to FIG. 13.

In the first and second exemplary embodiments, the short circuit plates 3A to 3D were provided at the end portion on the side of the wireless circuit unit 22 and the digital circuit unit 23 of the metal planes 2A to 2D, but they are not limited thereto. As shown in FIG. 11, along with the short circuit plates 3A to 3D, short circuit plates 3a to 3d may be provided at lateral positions of the metal planes 2A to 2D, so as to make a constitution that entirely encloses the current that flows through the ground plane with the metal planes 2A to 2D.

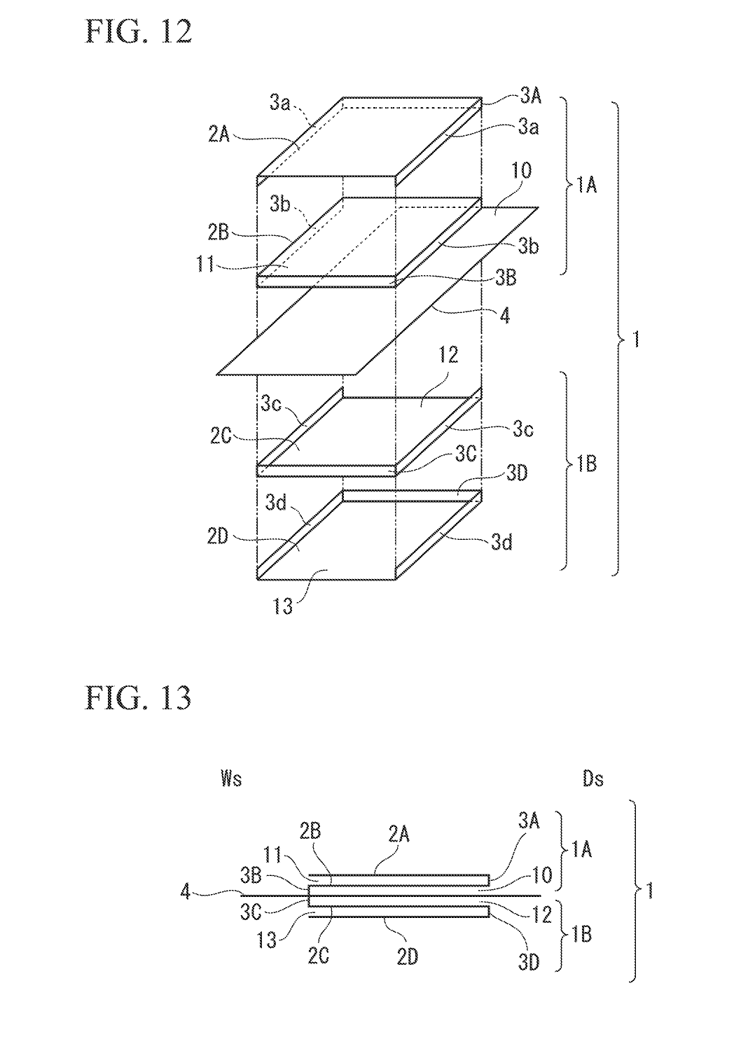

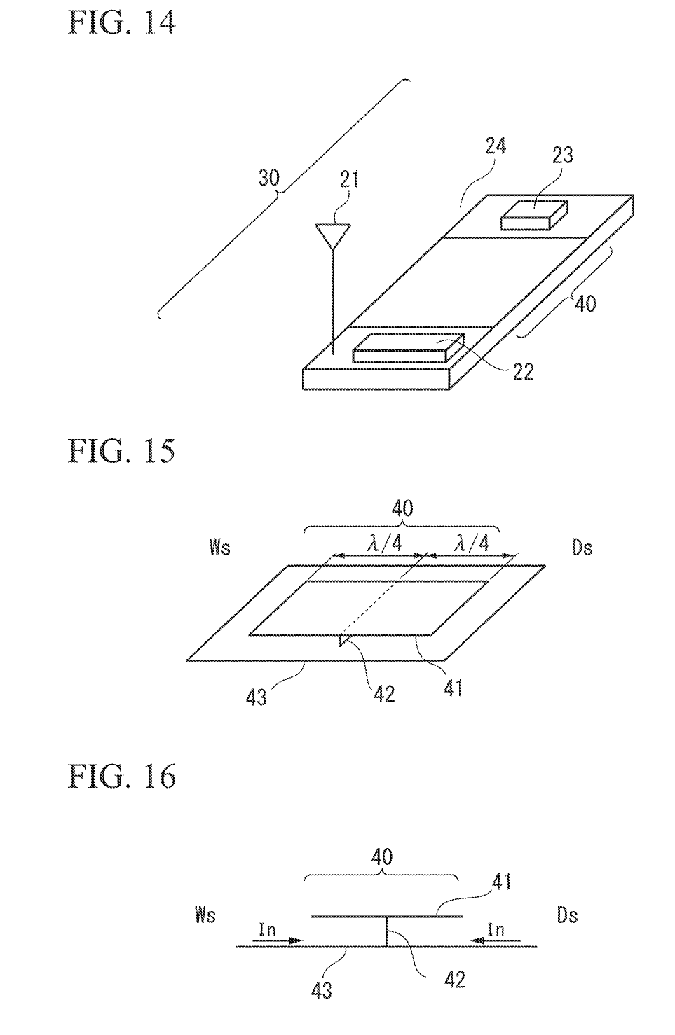

Hereinbelow, a noise suppression structure according to a third exemplary embodiment shall be described with reference to FIG. 11 to FIG. 13. FIG. 11 shows a perspective view of the noise suppression structure 1 according to the third exemplary embodiment of the present invention. FIG. 12 shows an exploded view of the noise suppression structure 1 of FIG. 11. FIG. 13 shows a side sectional elevation of the noise suppression structure 1 of FIG. 11.

As is clear by referring to these figures, this constitution forms short circuit plates 3a to 3d along with the short circuit plates 3A to 3D at the end plane portions of the substrate 50 in order to entirely enclose the ground layer 4 of the substrate 50.

In the first current control unit 1A, by elongating the short circuit plate 3A that is at the digital circuit unit 23 side Ds end portion of the metal plane 2A (second end portion) to both side portions, the short circuit plates 3a are formed. These short circuit plates 3A and 3a wrap around the metal plane 2A. By elongating the short circuit plate 3B that is at the wireless circuit unit 22 side Ws end portion of the metal plane 2B (first end portion) to both side portions, the short circuit plates 3b are formed. These short circuit plates 3B and 3b wrap around the metal plane 2B.

In the second current control unit 1B, by elongating the short circuit plate 3C that is at the wireless circuit unit 22 side Ws end portion of the metal plane 2C to both side portions, the short circuit plates 3c are formed. These short circuit plates 3C and 3c wrap around the metal plane 2C. By elongating the short circuit plate 3D that is at the digital circuit unit 23 side Ds end portion of the metal plane 2D to both side portions, the short circuit plate 3d is formed. These short circuit plates 3D and 3d wrap around the metal plane 2D.

In the noise suppression structure 1 of the third exemplary embodiment as described above, the open ends 10 to 13 that are formed at the end portions of the metal planes 2A to 2D are oriented toward the side Ds at which the digital circuit unit 23 is mounted and the sides Ws and As where the wireless circuit unit 22 and the antenna unit 21 are mounted. With this constitution, it is possible to suppress both the mixing in of noise from the digital circuit unit 23 side Ds to the wireless circuit unit 22 side Ws, and the mixing in of current from the wireless circuit unit 22 side Ws to the digital circuit unit 23 side Ds, and so noise suppression in a wireless application device becomes possible.

Moreover, by providing the notch portions 14 and 15 in the metal planes 2A to 2D in the same manner as the second exemplary embodiment, noise is suppressed across two frequency bands, and so a widening of the noise suppression frequency is achieved. Moreover, it is possible to effectively suppress noise current that flows in from the open ends 10 to 13 formed at the end portions of the noise suppression structure 1 by a portion enclosed by the metal planes 2A to 2D and the short circuit plates 3A to 3D, 3a to 3d.

The exemplary embodiments described above may be modified in the following manner.

### First Modified Example

In the aforedescribed first to third exemplary embodiments, the first current control unit 1A was provided on the upper side and the second current control unit 1B on the lower side so as to sandwich the ground layer 4. However, these current control units 1A and 1B are not limited to being provided above and below the ground layer 4. The current control units 1A and 1B may be provided on either one side. The two metal planes 2A and 2B/2C and 2D are provided in the current control units 1A and 1B, respectively, but not limited to this constitution. Using short circuit plates, many metal plates may be added and arranged in a layered shape.

### Second Modified Example

In the above second exemplary embodiment, the notch portions 14 and 15 that are provided in the metal planes 2A to 2D have a rectangular shape, but they are not limited thereto. By providing V-shaped or curved notch portions 14 and 15 in the metal planes 2A to 2D, the length of the transmission line may be set to the desired resonant length.

### Third Modified Example

In the second exemplary embodiment, a constitution was made that exhibits an effect toward frequencies on the lower side by making the length L of the metal planes 2A to 2D on the sides of the substrate 50 longer than the length S of the metal plates 2A to 2D near the center portion of the substrate where the notch portions 14 and 15 are (L>S). However, this may be reversed to make a constitution that suppresses noise on the high-frequency side. That is to say, by providing the notch portions 14 and 15 on both sides of the substrate 50, the length of the metal planes 2A to 2D at the sides of the substrate 50 where the notch portions 14 and 15 are becomes shorter than the length S of the metal planes 2A to 2D near the center of the substrate 50, and so a constitution of the metal planes 2A to 2D is achieved with the relation of L<S. That is to say, the placement location of the notch portions 14 and 15 in the substrate 50 is not particularly limited.

### Fourth Modified Example

In the second exemplary embodiment, by providing the rectangular notch portion 14 or 15 in each of the current control units 1A and 1B, two resonant frequencies were set, but it is not limited thereto. A plurality of the notch portions 14 and 15 may be provided in the current control units 1A and 1B, respectively. At this time, the size and location of the notch portions 14 and 15 may be altered. By providing two or more of the notch portions 14 and 15, setting three or more resonant frequencies becomes possible. This kind of constitution is preferred as a wide-band noise suppression structure for a wireless application device using multiband frequencies.

### Fifth Modified Example

In the noise suppression structure 1 of the first to third exemplary embodiments, the length of the metal planes 2A to 2D is set to the resonant length of ¼ of the wavelength, but is not limited thereto. The length of the metal planes 2A to 2D may also be set in consideration of the influence when the equivalent electrical length has changed in consideration of the wavelength shortening effect and coupling with the circumference and the like. Also, in consideration of the frequency band and the like, the resonant length may be se to a desired frequency within the band, such as the lower-limit frequency or the upper-limit frequency. Also, provided the effect is obtained, the length of the metal planes 2A to 2D may be determined based on trial and error.

### Sixth Modified Example

In the first to first exemplary embodiments, examples were shown of arranging the current control unit on the upper layer and lower layer of the ground layer 4 of the substrate 50, but it is not limited thereto. A signal pattern or power supply layer (plane) may be arranged on the upper side layer of the current control unit in the manner of an actual printed substrate 50. In that case, among the first current control unit 1A and the second current control unit 1B that are arranged so as to sandwich the ground layer 4, only the current control unit 1A or 1B of the side at which the signal pattern or the power supply layer is arranged may be used. For example, in the case of applying to a signal pattern, they may be arranged in the order of signal pattern, first current control unit 1A, and ground layer 4 from the upper layer of the substrate 50.

### Seventh Modified Example

The first to third exemplary embodiments showed examples of arranging the noise suppression structure 1 between the digital circuit unit 23 and the wireless circuit unit 22 (or the antenna unit 21), but the combination of intended circuit units is not limited to this. As understood by referring to FIG. 5, the noise suppression structure 1 may be arranged at any location between the digital circuit unit 23 and the wireless circuit unit 22.

Also, depending on the object or use, a constitution may be made in which only the wireless circuit unit 22 or only the antenna unit 21 is arranged on both sides.

### Eighth Modified Example

In the first to third exemplary embodiments, the noise suppression structure 1 may be arranged in the place where a plurality of digital circuit units 23 are mounted, and may be arranged with the open ends 10 to 13 oriented in the direction of wanting to suppress propagation of the noise current. For example, the digital circuit unit 23 may be arranged on both sides of the noise suppression structure 1, and the openings of the open ends 10 to 13 may be arranged so as to be oriented toward this digital circuit unit 23.

Hereinabove, the exemplary embodiments of the present invention were described in detail with reference to the drawings, but specific constitutions are not limited to these exemplary embodiments, and design modification which does not depart from the scope of the present invention are also included.

This application is based upon and claims the benefit of priority from Japanese patent application No. 2010-058237, filed Mar. 15, 2010, the disclosure of which is incorporated herein in its entirety by reference.

### INDUSTRIAL APPLICABILITY

The noise suppression structure of the present invention can be applied to electronic and electrical equipment including wireless application devices such as mobile phones, wireless personal computers, and personal digital assistants.

### DESCRIPTION OF REFERENCE SYMBOLS

1 Noise suppression structure
1A First current control unit
1B Second current control unit
2A Metal plane (second metal plane)
2B Metal plane (first metal plane)
2C Metal plane (first metal plane)
2D Metal plane (second metal plane)
3A Short circuit plate
3B Short circuit plate
3C Short circuit plate
3D Short circuit plate
4 Ground layer
10 Open end
11 Open end
12 Open end
13 Open end
14 Notch portion
15 Notch portion
21 Antenna unit
22 Wireless circuit unit
23 Digital circuit unit
24 Printed substrate
30 Wireless application device

1. A noise suppression structure comprising a current control unit provided on a ground layer and controlling current, the current control unit comprising:
a first metal plane that is provided above the ground layer with an interval therebetween, and having a first end portion and a second end portion on an opposite side of the first end portion;
a second metal plane that is provided above the first metal plane with an interval therebetween, and having a first end portion and a second end portion on an opposite side of the first end portion;
a first short circuit plate that is arranged at the first end portion of the first metal plane, and connects the first metal plane and the ground layer; and
a second short circuit plate that is arranged at the second end portion of the second metal plane, and connects the second metal plane and the first metal plane,
a first open end being formed at the second end portion of the first metal plane, and a second open end being formed at the first end portion of the second metal plane.

2. A noise suppression structure comprising a current control unit provided on a ground layer and controlling current, the current control unit comprising a first current control unit provided on an upper side of the ground layer, and a second current control unit provided on a lower side of the ground layer, the first current control unit and the second current control unit sandwiching the ground layer therebetween, and each of the first and second current control units comprising:
a first metal plane that is provided above the ground layer with an interval therebetween, and having a first end portion and a second end portion on an opposite side of the first end portion;
a second metal plane that is provided above the first metal plane with an interval therebetween, and having a first end portion and a second end portion on an opposite side of the first end portion;
a first short circuit plate that is arranged at the first end portion of the first metal plane, and connects the first metal plane and the ground layer; and
a second short circuit plate that is arranged at the second end portion of the second metal plane, and connects the second metal plane and the first metal plane;
a first open end being formed at the second end portion of the first metal plane, and a second open end being formed at the first end portion of the second metal plane.

3. The noise suppression structure according to claim 2, wherein each of the first and second current control units comprises:
a first transmission line that is constituted from the first metal plane, the first short circuit plate and the ground layer, and has the first open end; and
a second transmission line that is constituted from the second metal plane, the second short circuit plate and the first metal plane, and has the second open end.

4. The noise suppression structure according to claim 2, wherein the first and second current control units commonly use the ground layer, and the first and second current control units are arranged in a vertically symmetrical manner with respect to the ground layer.

5. The noise suppression structure according to claim 2, wherein the first and second current control units are mounted between a circuit and a circuit.

6. The noise suppression structure according to claim 5, wherein a digital circuit unit is arranged at one end portion of the first and second current control units, and a wireless circuit is arranged at an other end portion of the first and second current control units.

7. The noise suppression structure according to claim 6, wherein the first and second open ends are oriented in a direction in which a digital circuit unit, a wireless circuit, or an antenna unit of the wireless circuit is mounted.

8. The noise suppression structure according to claim 2, wherein a notch portion is provided in a portion of the first and second metal planes.

9. The noise suppression structure according to claim 8, wherein provision of the notch portion causes a length of side portions of the first and second metal planes is long, and a length near center is short.

10. The noise suppression structure according to claim 8, wherein at least two or more notch portions having a rectangular shape, V-shape, or curved shape are provided in the first and second metal planes.

11. The noise suppression structure according to claim 3, wherein the first and second current control units commonly use the ground layer, and the first and second current control units are arranged in a vertically symmetrical manner with respect to the ground layer.

12. The noise suppression structure according to claim 3, wherein the first and second current control units are mounted between a circuit and a circuit.

13. The noise suppression structure according to claim 4, wherein the first and second current control units are mounted between a circuit and a circuit.

14. The noise suppression structure according to claim 9, wherein at least two or more notch portions having a rectangular shape, V-shape, or curved shape are provided in the first and second metal planes.
